(19) United States
(12) Patent Application Publication
(10) Pub. No.: US 2026/0156751 A1
(43) Pub. Date: Jun. 4, 2026

(54) ELECTRONIC DEVICE AND METHOD FOR MANUFACTURING SAME

(71) Applicant: Sharp Display Technology Corporation, Kameyama City (JP)

(72) Inventors: Naoki HOSOYA, Kameyama City (JP); Akira IEYAMA, Kameyama City (JP); Mizuho SHIROTORI, Kameyama City (JP)

(21) Appl. No.: 19/369,591

(22) Filed: Oct. 27, 2025

(30) Foreign Application Priority Data
Nov. 29, 2024 (JP) 2024-208823

(51) Int. Cl. H05K 1/14

(52) U.S. Cl. CPC H05K 1/147; H05K 2201/10954

(57) ABSTRACT

An electronic device includes an electronic element substrate including electronic elements and wiring on a first substrate, a second substrate disposed on the first substrate to expose a terminal area where terminals of the wiring are formed, a flexible circuit board including circuitry provided on a flexible film, an anisotropic conductive resin layer disposed to electrically connect the circuitry to the terminals, and a moisture-proof resin portion formed in contact with the first and second substrates and the film at a position closer to the second substrate than the anisotropic conductive resin layer is, and including a first portion between the first substrate and the film, a second portion between the second substrate and the film, and a third portion on an opposite surface, of the film, facing away from a surface on which the anisotropic conductive resin layer is formed. The first, second, and third portions are formed continuously.

### BACKGROUND

### 1. Field

The present disclosure relates to an electronic device and a method for manufacturing the same, and more particularly to an electronic device that includes an electronic element substrate and a flexible circuit board (flexible printed circuit: FPC) and a method for manufacturing the same.

### 2. Description of the Related Art

In an electronic device that includes an electronic element substrate and a flexible circuit board, an ACF (Anisotropic Conducting Film) is used when connecting the flexible circuit board to the electronic element substrate, for example, as disclosed in Japanese Unexamined Patent Application Publication No. 6-203642.

For example, in a liquid crystal display device, with the use of an ACF, an FPC on which a chip of a control circuit (IC) is mounted is connected to an active matrix substrate of a liquid crystal display panel. The FPC on which the IC chip is mounted is called “chip on film” (COF). COF is sometimes regarded as a mode of packaging of an IC chip. An FPC mentioned in this specification is a broad concept that encompasses a wide variety of flexible circuit boards, including but not limited to tape automated bonding (TAB).

A structure in which an FPC is connected to an electronic element substrate using an ACF is required to meet moisture-proof (resistance-to-moisture) requirements and bonding-strength requirements, in addition to stability in electric connection.

Japanese Unexamined Patent Application Publication No. 6-203642 discloses an ACF in which a moisture-proof layer is provided at a part or the whole of the periphery of an anisotropic conductive resin layer. According to Japanese Unexamined Patent Application Publication No. 6-203642,using an ACF that includes a moisture-proof layer enhances moisture-proof property and bonding strength.

However, according to a study conducted by the inventors of the present application, even with the use of the ACF that includes the moisture-proof layer disclosed in Japanese Unexamined Patent Application Publication No. 6-203642, sufficient bonding strength cannot sometimes be obtained.

The present disclosure provides an electronic device that offers excellent moisture-proof property and great bonding strength for a structure in which an FPC is connected to an electronic element substrate using an ACF.

### SUMMARY

According to an embodied aspect of the present disclosure, an electronic device stated in Items below is provided.

### Item 1

An electronic device comprising: an electronic element substrate including a first substrate, a plurality of electronic elements formed on the first substrate, and a plurality of wiring lines connected to the plurality of electronic elements; a second substrate disposed on the first substrate in such a way as to expose a terminal area where a plurality of terminals of the plurality of wiring lines of the first substrate is formed; a flexible circuit board including a film and circuitry, the film being flexible, the circuitry being provided on the film; an anisotropic conductive resin layer disposed between the terminal area of the first substrate and the film in such a way as to electrically connect the circuitry to the plurality of terminals; and a moisture-proof resin portion formed in contact with the first substrate, the second substrate, and the film, wherein the moisture-proof resin portion is formed at a position closer to the second substrate than the anisotropic conductive resin layer is, the moisture-proof resin portion includes a first portion, a second portion, and a third portion, the first portion being a portion between the first substrate and the film, the second portion being a portion between the second substrate and the film, the third portion being a portion on an opposite surface, of the film, facing away from a surface on which the anisotropic conductive resin layer is formed, and the first portion, the second portion, and the third portion are formed continuously.

### Item 2

A method for manufacturing the electronic device according to Item 1, the method comprising: preparing a flexible circuit board to which a moisture-proof resin material has been applied at an area on the film where the first portion of the moisture-proof resin portion is to be formed; putting an anisotropic conductive resin material on the terminal area of the first substrate; and performing thermal compression bonding of the flexible circuit board to the first substrate in a state of such arrangement that the circuitry of the flexible circuit board is electrically connected to the plurality of terminals on the first substrate via the anisotropic conductive resin material, wherein in the performing of the thermal compression bonding, the anisotropic conductive resin material cures to form into the anisotropic conductive resin layer, and, in addition, the moisture-proof resin material melts, flows, and cures to form into the moisture-proof resin portion.

### BRIEF DESCRIPTION OF THE DRAWINGS

FIG. 1 is a schematic cross-sectional view of a liquid crystal display device according to an embodiment of the present disclosure corresponding to a section along a line I-I of FIG. 2;

FIG. 2 is a schematic plan view of the liquid crystal display device;

FIG. 3 is a schematic cross-sectional view of a flexible circuit board, illustrated with a moisture-proof resin material applied, used in the manufacture of the liquid crystal display device corresponding to a section along a line III-III of FIG. 4;

FIG. 4 is a schematic plan view of the flexible circuit board, illustrated with the moisture-proof resin material applied;

FIG. 5 is a schematic cross-sectional view of a liquid crystal display device according to another embodiment of the present disclosure corresponding to a section along a line V-V of FIG. 6;

FIG. 6 is a schematic plan view of the liquid crystal display device;

FIG. 7 is a schematic plan view of the flexible circuit board, illustrated with a moisture-proof resin material applied, used in the manufacture of the liquid crystal display device; and

FIG. 8 is a schematic plan view of a flexible circuit board, illustrated with a moisture-proof resin material applied, used in the manufacture of a liquid crystal display device according to still another embodiment of the present disclosure.

### DESCRIPTION OF THE EMBODIMENTS

With reference to the drawings, an electronic device and a method for manufacturing the same according to some embodiments of the present disclosure will be described below. An active-matrix-type liquid crystal display device will be described as an example of an electronic device. An electronic device according to an embodiment of the present disclosure, however, is not limited to a liquid crystal display device, and may be any of various types of electronic devices, including but not limited to other display devices such as an organic electroluminescent (EL) display device.

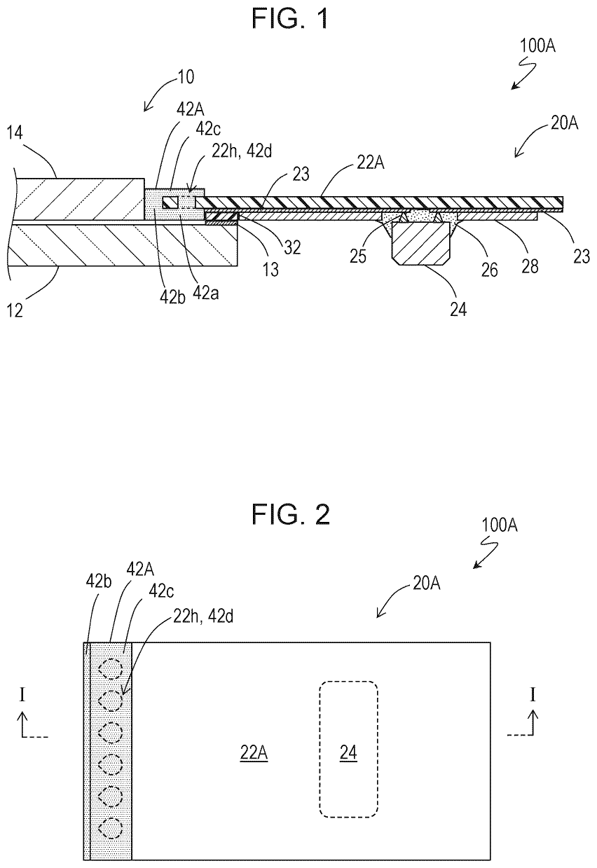

FIG. 1 is a schematic cross-sectional view of a liquid crystal display device 100A according to an embodiment of the present disclosure. FIG. 2 is a schematic plan view of the liquid crystal display device 100A. The section in FIG. 1 corresponds to a section along a line I-I of FIG. 2; however, the illustration of a liquid crystal display panel 10, which is illustrated in FIG. 1, is omitted in FIG. 2.

The liquid crystal display device 100A includes the liquid crystal display panel 10 and an FPC 20A, on the latter of which a control circuit (IC) is COF-mounted. The FPC 20A is connected to the liquid crystal display panel 10 using an ACF 32.

The liquid crystal display panel 10 includes an active matrix substrate 12 (denoted by the same reference numeral as that of a glass substrate 12), meaning the glass substrate 12 on which thin-film transistors (TFT), pixel electrodes, and wiring are formed, a counter substrate 14 (denoted by the same reference numeral as that of a glass substrate 14), meaning the glass substrate 14 on which a common electrode and a color filter layer, etc. (none of which is illustrated) are formed, and a liquid crystal layer (not illustrated) provided between these two substrates. The counter substrate 14 is disposed in such a way as to expose a terminal area where a plurality of terminals 13 of a plurality of wiring lines of the active matrix substrate 12 is formed.

The FPC 20A includes a film 22A that is flexible (for example, a polyimide film) and circuitry formed on the film 22A. The circuitry includes, for example, a driving IC 24, wiring 23, and the like. The driving IC 24 is connected to the wiring 23 using a gold bump 25, and is fixed on the film 22A using a sealing resin 26. The wiring 23 is covered by, for example, a solder resist 28 in such a way as to expose a portion connected electrically to the terminals 13 of the active matrix substrate 12.

The liquid crystal display device 100A includes an anisotropic conductive resin layer 32, which is disposed between the terminal area of the glass substrate 12 and the film 22A and electrically connects the circuitry (in this example, the wiring 23) on the film 22A to the plurality of terminals 13 on the glass substrate 12.

The liquid crystal display device 100A further includes a moisture-proof resin portion 42A, which is formed in contact with the glass substrate 12, the glass substrate 14, and the film 22A. The moisture-proof resin portion 42A is formed at a position closer to the glass substrate 14 than the anisotropic conductive resin layer 32 is. The moisture-proof resin portion 42A includes a first portion 42a, which is a portion between the glass substrate 12 and the film 22A, a second portion 42b, which is a portion between the glass substrate 14 and the film 22A, and a third portion 42c, which is a portion on the opposite surface, of the film 22A, facing away from the surface on which the anisotropic conductive resin layer 32 is formed. The first portion 42a, the second portion 42b, and the third portion 42c are formed integrally. The meaning of this sentence, “The first portion 42a, the second portion 42b, and the third portion 42c are formed integrally”, is that there is no interface formed between these portions.

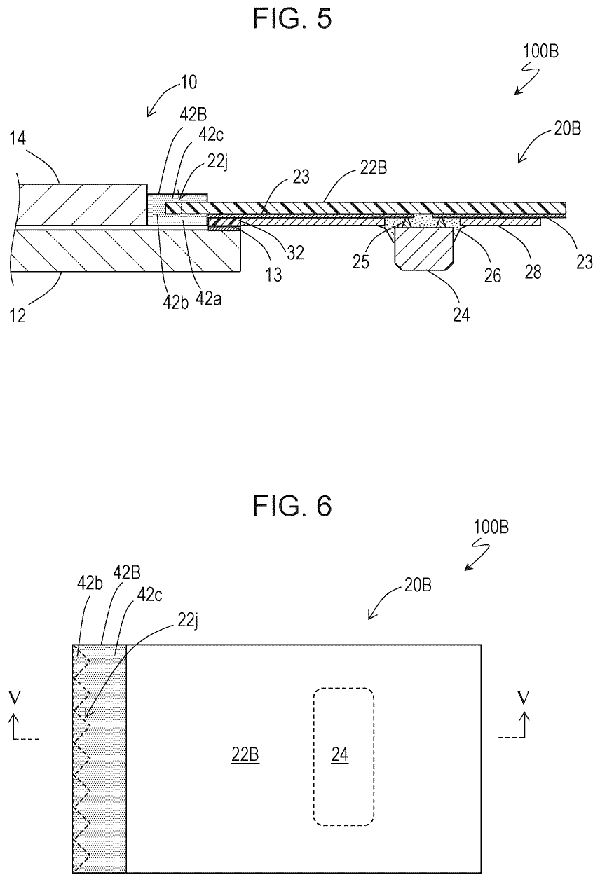

The film 22A includes a through hole 22h. The moisture-proof resin portion 42A includes a fourth portion 42d formed in the through hole 22h. The fourth portion 42d is formed integrally with the first portion 42a and the third portion 42c. As disclosed later by way of example, the fourth portion 42d may be omitted (see FIG. 5, for example).

The liquid crystal display device 100A includes the moisture-proof resin portion 42A including at least the first portion 42a, the second portion 42b, and the third portion 42c. Since these portions are formed integrally, it is possible to improve bonding strength between the film 22A and the glass substrate 12. The moisture-proof resin portion 42A can, of course, suppress or prevent the entry of moisture into the anisotropic conductive resin layer 32.

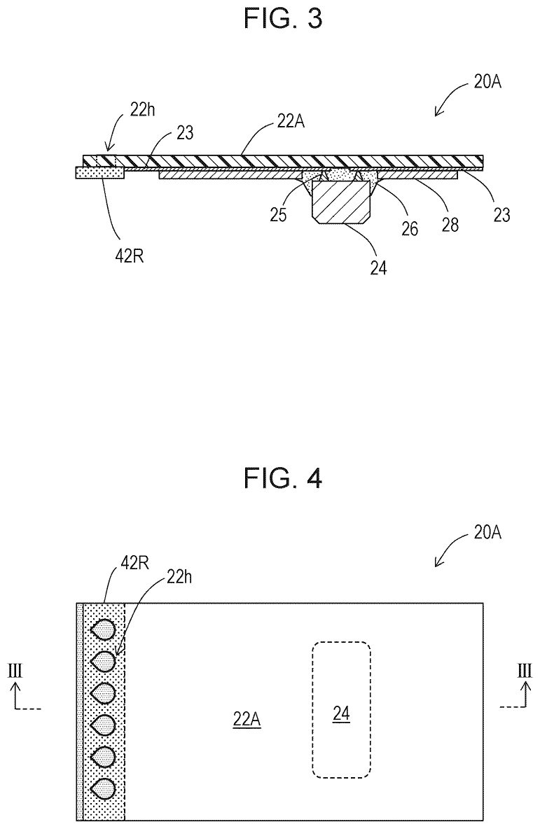

Next, with reference to FIGS. 3 and 4, a method for manufacturing the liquid crystal display device 100A will now be described. FIG. 3 is a schematic cross-sectional view of a flexible circuit board 20A, illustrated with a moisture-proof resin material 42R applied, used in the manufacture of the liquid crystal display device 100A. FIG. 4 is a schematic plan view of the flexible circuit board 20A, illustrated with the moisture-proof resin material 42R applied.

The liquid crystal display device 100A can be manufactured using, for example, the following method.

A first step is, as illustrated in FIG. 3, to prepare the flexible circuit board 20A to which the moisture-proof resin material 42R has been applied at an area on the film 22A where the first portion 42a of the moisture-proof resin portion 42A is to be formed. In a case where the moisture-proof resin material 42R is a solid, it may be applied in such a way as to protrude partially beyond an end surface, of the film 22A, facing toward a side surface of the glass substrate 14 as illustrated in FIG. 3; alternatively, it may be applied in such a way as to be flush with the end surface, of the film 22A, facing toward the side surface of the glass substrate 14.

Next, an anisotropic conductive resin material is put on the terminal area of the glass substrate 12. A known method can be used for this step. For example, an ACF that includes a layer of an anisotropic conductive resin material (a material that contains conductive particles dispersed in a thermosetting resin) formed on a separator film is put on the terminal area of the glass substrate 12 using a roll, and then, the separator film is removed.

Next, thermal compression bonding of the flexible circuit board 20A to the glass substrate 12 is performed in a state of such arrangement that circuitry (the exposed portion of the wiring 23) of the flexible circuit board 20A is electrically connected to the plurality of terminals 13 on the glass substrate 12 via the anisotropic conductive resin material. The thermal compression bonding is performed by pressing a thermal compression bonding head onto a predetermined position. In this process, the anisotropic conductive resin material cures to form into the anisotropic conductive resin layer 32. In addition, in this process, the moisture-proof resin material 42R melts, flows from a gap between the film 22A and the glass substrate 12 into a gap between the film 22A and the glass substrate 14, and further reaches onto the opposite surface, of the film 22A, facing away from the surface on which the anisotropic conductive resin layer 32 is formed. Moreover, the moisture-proof resin material 42R flows into the through hole 22h of the film 22A and then reaches onto the opposite surface, of the film 22A, facing away from the surface on which the anisotropic conductive resin layer 32 is formed. The moisture-proof resin portion 42A that includes at least the first portion 42a, the second portion 42b, and the third portion 42c is formed in this way.

If the through hole 22h is provided as a path for the flow of the moisture-proof resin material 42R, it becomes easier for the moisture-proof resin material 42R to flow onto the opposite surface, of the film 22A, facing away from the surface on which the anisotropic conductive resin layer 32 is formed. Therefore, an effect of suppressing or preventing an excessive flow of the moisture-proof resin material 42R into the gap between the film 22A and the glass substrate 14, otherwise resulting in climbing onto the glass substrate 14 to form a part of the moisture-proof resin portion 42A thereat.

The through hole 22h may preferably have a shape of being tapered toward the glass substrate 14 when viewed in a direction normal to the film 22A. For example, as disclosed here by way of example, forming the through hole 22h into a sharp-pointed shape toward a direction in which the moisture-proof resin material 42R flows out makes it easier for the moisture-proof resin material 42R having flowed out of the through hole 22h and the moisture-proof resin material 42R having come through the gap between the glass substrate 14 and the film 22A to merge into one on the film 22A. The opposite-side shape of the through hole 22h may be, for example, as disclosed here by way of example, an arc.

As the ACF, an ACF that is commercially available may be used. In the ACF, an anisotropic conductive resin material is formed like a film on a separator (for example, a PET film). The anisotropic conductive resin material is, for example, a material obtained by dispersing nickel particles (having a particle diameter of 2 μm or greater and 3 μm or less) or metal-film-coated plastic particles (4 μm, 5 μm, or 10 μm) in thermosetting acrylic resin. The thickness of the anisotropic conductive resin material is, for example, approximately 10 μm, the width thereof is, for example, within a range from approximately 1.5 mm to approximately 1.7 mm, and the length thereof is greater than the length of an edge of the film 22A (for example, 40 to 45 mm).

Thermosetting acrylic resin can be used as the moisture-proof resin material. Those that are widely used in electronic parts can be used as thermosetting acrylic resin that has moisture-proof property. The moisture-proof resin material is applied along edges of the film 22A at a width of, for example, 1.5 mm or greater and 2.0 mm or less.

The conditions of applying heat and pressure by means of the thermal compression bonding head are, for example, as follows: Temperature: 150° C. to 210° C.; Pressure: 2 MPa to 7 MPa; Time: 4 sec. to 15 sec. The conditions can be adjusted by changing the type of the acrylic resin.

The through hole 22h formed in the film 22A has, for example, an equivalent circle diameter of 1.0 mm or greater and 1.5 mm or less. A plurality of through holes 22h may preferably be formed such that their total area is, for example, 50% or greater and 75% or less of the area (for example, 1.5 mm or greater and 2.0 mm or less in width ×40 to 45 mm in length) of the moisture-proof resin material applied under the film 22A. If the total area of the plurality of through holes 22h is less than 50% or greater than 75%, it could happen that the effect of improving the bonding strength of the film 22A is not obtained enough due to insufficient integral forming of the moisture-proof resin portion 42A.

The above-described method for manufacturing the liquid crystal display device 100A makes it possible to form the anisotropic conductive resin layer 32 and the moisture-proof resin portion 42A in the same step. Therefore, mass productivity does not decrease.

Next, with reference to FIGS. 5 to 7, a liquid crystal display device 100B according to an embodiment of the present disclosure will now be described. The same reference signs will be assigned to components having the same function, and an explanation of them will sometimes be omitted.

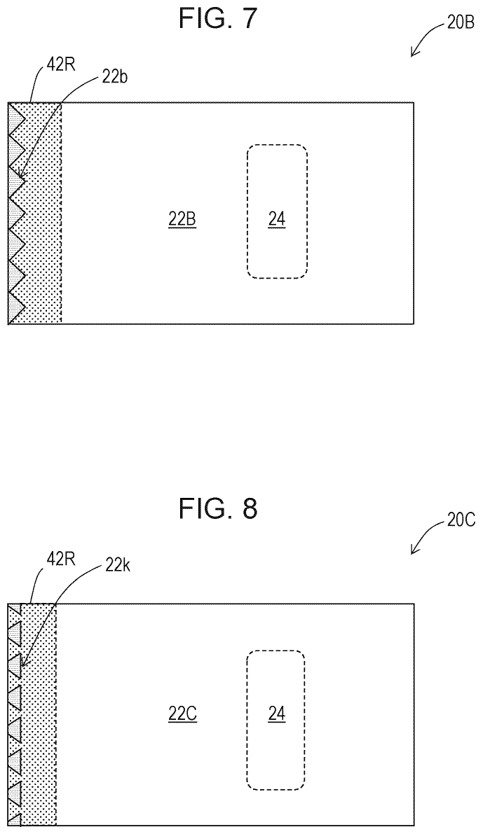

FIG. 5 is a schematic cross-sectional view of the liquid crystal display device 100B. FIG. 6 is a schematic plan view of the liquid crystal display device 100B. The section in FIG. 5 corresponds to a section along a line V-V of FIG. 6. FIG. 7 is a schematic plan view of a flexible circuit board 20B, illustrated with the moisture-proof resin material 42R applied, used in the manufacture of the liquid crystal display device 100B.

As illustrated in these drawings, the flexible circuit board 20B can be used in place of the flexible circuit board 20A of the liquid crystal display device 100A.

The flexible circuit board 20B does not include the through hole 22h of the flexible circuit board 20A. Instead, the flexible circuit board 20B includes a cutout 22j in its end surface facing toward a side surface of the glass substrate 14, and the second portion 42b of a moisture-proof resin portion 42B includes a portion encroaching into the cutout 22j. The cutout 22j has a shape of a concatenation of triangles. However, this does not imply any limitation. The size of the cutout 22j is, for example, 0.7 mm or greater and 1.4 mm or less. The total area of the cutout 22j may preferably be, for example, 50% or greater and 75% or less of the area (for example, 1.5 mm or greater and 2.0 mm or less in width ×40 to 45 mm in length) of the moisture-proof resin material applied under the film 22A. If the total area of the cutout 22j is less than 50% or greater than 75%, it could happen that the effect of improving the bonding strength of a film 22B is not obtained enough due to insufficient integral forming of the moisture-proof resin portion 42B.

The shape of the cutout is not limited to the above example. For example, it may be a cutout 22k that has a shape of being tapered toward the glass substrate 14 when viewed in a direction normal to a film 22C, as in the film 22C of a flexible circuit board 20C illustrated in FIG. 8.

According to an embodiment of the present disclosure, an electronic device such as a display device that offers excellent moisture-proof property and great bonding strength is provided for a structure in which an FPC is connected to an electronic element substrate using an ACF.

The present disclosure contains subject matter related to that disclosed in Japanese Priority Patent Application JP 2024-208823 filed in the Japan Patent Office on Nov. 29, 2024, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An electronic device comprising:
an electronic element substrate including a first substrate, a plurality of electronic elements formed on the first substrate, and a plurality of wiring lines connected to the plurality of electronic elements;
a second substrate disposed on the first substrate in such a way as to expose a terminal area where a plurality of terminals of the plurality of wiring lines of the first substrate is formed;
a flexible circuit board including a film and circuitry, the film being flexible, the circuitry being provided on the film;
an anisotropic conductive resin layer disposed between the terminal area of the first substrate and the film in such a way as to electrically connect the circuitry to the plurality of terminals; and
a moisture-proof resin portion formed in contact with the first substrate, the second substrate, and the film, wherein
the moisture-proof resin portion is formed at a position closer to the second substrate than the anisotropic conductive resin layer is,
the moisture-proof resin portion includes a first portion, a second portion, and a third portion, the first portion being a portion between the first substrate and the film, the second portion being a portion between the second substrate and the film, the third portion being a portion on an opposite surface, of the film, facing away from a surface on which the anisotropic conductive resin layer is formed, and
the first portion, the second portion, and the third portion are formed continuously.

2. The electronic device according to claim 1, wherein
the film includes a through hole,
the moisture-proof resin portion further includes a fourth portion formed in the through hole, and
the fourth portion is formed integrally with the first portion and the third portion.

3. The electronic device according to claim 2, wherein
the through hole has a shape of being tapered toward the second substrate when viewed in a direction normal to the film.

4. The electronic device according to claim 1, wherein
an end surface, of the film, facing toward a side surface of the second substrate includes a cutout, and
the second portion includes a portion encroaching into the cutout.

5. A method for manufacturing the electronic device according to claim 1, the method comprising:
preparing a flexible circuit board to which a moisture-proof resin material has been applied at an area on the film where the first portion of the moisture-proof resin portion is to be formed;
putting an anisotropic conductive resin material on the terminal area of the first substrate; and
performing thermal compression bonding of the flexible circuit board to the first substrate in a state of such arrangement that the circuitry of the flexible circuit board is electrically connected to the plurality of terminals on the first substrate via the anisotropic conductive resin material, wherein
in the performing of the thermal compression bonding, the anisotropic conductive resin material cures to form into the anisotropic conductive resin layer, and, in addition, the moisture-proof resin material melts, flows, and cures to form into the moisture-proof resin portion.
